(19) United States
(12) Patent Application Publication
(10) Pub. No.: US 2008/0315891 A1
(43) Pub. Date: Dec. 25, 2008

(54) Transmission line pulse testing with reflection control

(76) Inventor: Evan Grund, San Jose, CA (US)

Correspondence Address: NIXON PEABODY, LLP, 401 9TH STREET, NW, SUITE 900, WASHINGTON, DC, 20004-2128, US

(21) Appl. No.: 12/152,338

(22) Filed: May 14, 2008

Related U.S. Application Data
(60) Provisional application No. 60/930,094, filed on May 14, 2007.

(51) Int. Cl. G01R 31/11

(52) U.S. Cl. 324/534

(57) ABSTRACT

A Transmission Line Pulse (TLP) testing system is disclosed that has a negative pulse inverter circuit that prevents large negative reflections which typically occur after the initial TLP pulse is applied to a low impedance device under test (DUT). Avoiding repetitive reflections, which naturally occur in TLP systems, prevents inducing DUT damage and confusing testing results. The pulse inverter circuit reduces reflections to lower levels than prior art TLP configurations, and can also be combined with known techniques to further reduce reflections for different impedance DUTs.

### CROSS REFERENCE TO RELATED APPLICATION

This application claims the benefit of U.S. Provisional Application No. 60/930,094, filed May 14, 2007, which is incorporated by reference herein.

### BACKGROUND OF THE INVENTION

1. Field of the Invention

The invention relates in general to test systems for integrated circuits, especially for testing with a transmission line pulser.

2. Description of the Related Art

Transmission Line Pulse (TLP) systems provide an incident stress pulse to a device under test (DUT) and monitor the reflected pulse to determine the current and voltage response of the DUT. Thus, reflections are a normal part of TLP system operation. However, these reflections can re-reflect from the TLP pulser and be sent back to the DUT. Re-reflections occur with any DUT, with the exception of a resistive DUT having a resistance that matches the pulse delivery cable impedance. However, re-reflections are especially problematic when testing forward biased diodes at high current, as shown in FIG. 1, because the re-reflected voltages can be very large and may cause the diode to enter reverse breakdown and dissipate significant power from the re-reflection, sometimes causing device damage. To avoid such secondary pulses and their unintentional damage, prior art TLP systems employ various techniques that reduce re-reflections.

TLP systems produce large reflected reverse polarity pulses when testing any low impedance DUT, including diodes. The diodes commonly used in today's Electro Static Discharge (ESD) protection structures are not normally subjected to large reverse voltages, and therefore are not designed to withstand these large reverse pulses. It can be difficult for the TLP user to differentiate diode failure due to heating caused by high forward currents from oxide breakdown due to large reverse voltages.

The voltage seen across the DUT is the incident pulse plus the reflected pulse. The reflected pulse is determined by the impedance mismatch between the cable (with ZCABLE impedance) and the DUT (with ZDUT impedance), specifically

$${v}_{REFLECTED} = {v}_{INCIDENT} \frac{{z}_{DUT} - {z}_{CABLE}}{{z}_{DUT} + {z}_{CABLE}} .$$

Therefore, the DUT voltage is

$${v}_{DUT} = {v}_{REFLECTED} + {v}_{INCIDENT} = {v}_{INCIDENT} \cdot \frac{2 {z}_{DUT}}{{z}_{DUT} + {z}_{CABLE}} .$$

For a DUT impedance that equals the cable impedance there is no reflection, while there is a reflection of the same polarity (in phase) for DUT impedances greater than the cable's. When the DUT impedance is lower than the cable impedance, a negative pulse is reflected (a pulse of opposite polarity i.e., 180 degrees out of phase). Consequently, for low impedance DUTs, a negative reflection is generated from a positive pulse. Diodes at moderate to high forward conduction have low impedances, which is why these devices are especially problematic when they are tested at high currents.

A popular misconception about TLP systems is that they have 50-ohm output impedances. While compatible with 50-ohm cables, the output impedance of a basic TLP system is best described as a 50-ohm output connector cable that has an open circuit at the pulser end. Any pulse that is applied to the output connector cable of a TLP system will travel down the cable and reflect back to the output of the pulser modified only by the small cable losses. Because any device under test (DUT) that does not match the 50-ohm cable impedance will produce a reflection, reflected pulses from the DUT are re-reflected by the TLP system. These re-reflected pulses will stress the DUT again. This process will be repeated until the pulse energy is incrementally absorbed by the DUT or dissipated in the resistive losses of the cables. Therefore, all TLP systems should have a means to reduce or eliminate re-reflections.

To demonstrate the magnitude of the reflection problem, FIG. 1 a shows a TLP system that provides a 250 volt incident pulse that travels down a 50-ohm cable to the diode under test that will have a forward voltage drop of 6V with 9.9A forward bias current. The voltage as a function of time diagram in FIG. 1b shows repeated stressing of the DUT by re-reflected pulses having a magnitude of close to negative 500 volts when re-reflection control is not included in the TLP tester design.

Using attenuators is a common engineering practice to reduce signal levels. FIG. 2a shows an attenuator added in the pulse path to reduce reflections. FIG. 2b illustrates the voltage versus time diagram produced by the circuit showing the re-reflected pulses being reduced when testing a diode. Unfortunately, the attenuator also reduces the incident pulse. The incident pulse power available for testing at high current may need to be significantly reduced to control re-reflections.

FIG. 3a illustrates an alternate prior art solution for re-reflection control. FIG. 3a is a simplified schematic electrical diagram of a prior art TLP testing system with terminated charge-line control of reflections, and FIG. 3b illustrates the voltage versus time diagram produced by the circuit showing the re-reflected pulses being reduced when testing a diode. To illustrate the effect of small resistance changes, reflections from incremented changes of 1 ohm in the termination resistance is shown. Reverse voltage pulses are terminated in a diode and 50-ohm resistor circuit placed at the end of charge-line cable whose impedance is designed to equal the charge line cable's characteristic impedance. Only if the series resistance of the diode and resistor termination is exactly equal to the cable impedance will the reflection be totally absorbed without re-reflection. Due to the small but not insignificant diode resistance that changes with current level, matching exactly the cable impedance (which also typically has a tolerance of 2% or ±1 ohm) is impossible for all reflection currents. The terminated charge-line provided by the diode resistor circuit will not remove any re-reflections when the DUT has an impedance of greater than 50 ohms.

The technique of TLP Time Domain Reflection and Transmission (TDRT) comprises the substitution of a 50Ω cable having a 50Ω termination (such as an oscilloscope input) for the DUT ground. This adds 50Ω to the DUT impedance, so the reflections are small and never inverted or negative. When used with an attenuator, as seen in FIG. 4a, only small reflections are created by TLP measurement of small valued resistances, as seen in FIG. 4b. However, when testing diodes, which have a capacitance that is maximum at zero voltage, when the incident pulse arrives, a negative spike reflection can occur as seen in FIG. 4c.

It is typically the case that high current pulses are applied to low impedance parts in testing ESD protection structures using TLP techniques. A simple example is a rail clamp diode. At very low voltages, below the threshold forward voltage of the diode, a diode presents a high impedance. As the voltage pulse level is increased, the diode is forward biased and the apparent diode impedance begins to approach its dynamic on resistance, which is often a few ohms or less. Note that apparent impedance means the resistance indicated by the slope of a line drawn from any point on the I-V curve back to the origin. This is greater than the dynamic or on resistance, which is the slope of a line drawn through the I-V curve points. As the TLP pulse power is increased, the diode impedance becomes very low and a low voltage with large current is measured at this DUT. The incident voltage pulse produces a negative reflected pulse when it impacts the DUT. The negative pulse is re-reflected from the pulser back to the DUT, which can drive the diode into breakdown where it dissipates large power and can be destroyed before the forward conduction limits are reached. Therefore, a need exists in the art of TLP testing for a circuit that can reduce the reflections that are applied to ICs under test. With shrinking dimensions and lower voltage operating levels of new ICs, driving the gate oxides to become thinner, newer devices are even more sensitive to negative voltage pulses. Therefore, it is even more important today and in the future to limit reverse reflected voltage pulses in TLP testing systems.

### SUMMARY OF THE INVENTION

Accordingly, it is an object of the present invention to provide a circuit, system, and method for TLP testing of integrated circuits that does not produce reverse voltage stresses at a device under test. This invention is a circuit added to a TLP test system that causes all negative reflections to be inverted. The inventive technique also may use an attenuator to partly absorb the reverse reflections during each re-reflection.

The improved solution to re-reflection control is to add a small attenuator and a diode (without a series resistor) in the TLP delivery line as seen in FIG. 5. This new diode inverts the echo pulses, preventing reverse biasing of the DUT while the attenuator reduces the reflection magnitudes by its energy absorption. This reversing diode does not need to have the very large reverse breakdown characteristics of a charge-line terminating diode, nor does it need to conduct the full reflected pulse current. A cable between the reversing diode and the DUT is required to cause the incident and reflected pulses to be separated a sufficient amount to enable the reflection pulse to be isolated from the incident pulse. The key part of the invention is “negative reflected pulse inverter” circuit which enables the TLP system to prevent reverse biasing of the diode or other DUT.

These and other objects, features and advantages of the present invention will become apparent to those skilled in the art after reading the following detailed description of the preferred embodiments that are illustrated in the several accompanying drawings.

### BRIEF DESCRIPTION OF THE DRAWINGS

The present invention can be better understood with reference to the drawings.

FIG. 1a is a simplified schematic electrical diagram of a prior art TLP testing system without re-reflection control, and FIG. 1b illustrates the voltage versus time diagram showing the re-reflected pulses that are produced by the circuit when testing a diode.

FIG. 2a is a simplified schematic electrical diagram of a prior art TLP testing system with attenuator control of reflections, and FIG. 2b illustrates the voltage versus time diagram produced by the circuit showing the re-reflected pulses being reduced when testing a diode.

FIG. 3a is a simplified schematic electrical diagram of a prior art TLP testing system with terminated charge-line control of reflections, and FIG. 3b illustrates the voltage versus time diagram produced by the circuit showing the re-reflected pulses being reduced when testing a diode. To illustrate the effect of small resistance changes, reflections from incremented changes of 1 ohm in the termination resistance is shown.

FIG. 4a is a simplified schematic electrical diagram of a prior art TLP testing system with a Time Domain Reflection and Transmission (TDRP) TLP configuration and attenuator control of reflections, and voltage versus time diagrams are illustrated at FIGS. 4b and 4c showing the re-reflected pulses produced by this circuit being reduced when testing a diode. Voltage versus time diagram 4b shows the circuit response when testing and ideal diode, and diagram 4C shows the circuit response when a practical actual diode that includes parasitic capacitance is tested.

FIG. 5 is a simplified schematic electrical diagram of a first TLP system according to the present invention.

FIG. 6 is a voltage versus time diagram produced by the inventive TLP tester shown in FIG. 5.

FIG. 7 is a simplified schematic electrical diagram of a second embodiment of a TLP system according to the present invention.

FIG. 8 is a simplified schematic electrical diagram of a third embodiment of a TLP system according to the present invention including an attenuator in a Time Domain Reflection and Transmission TDRT configuration.

FIG. 9 is a simplified schematic electrical diagram of a fourth embodiment of a TLP system according to the present invention including two diodes that are alternately connected to the transmission path by a relay switch.

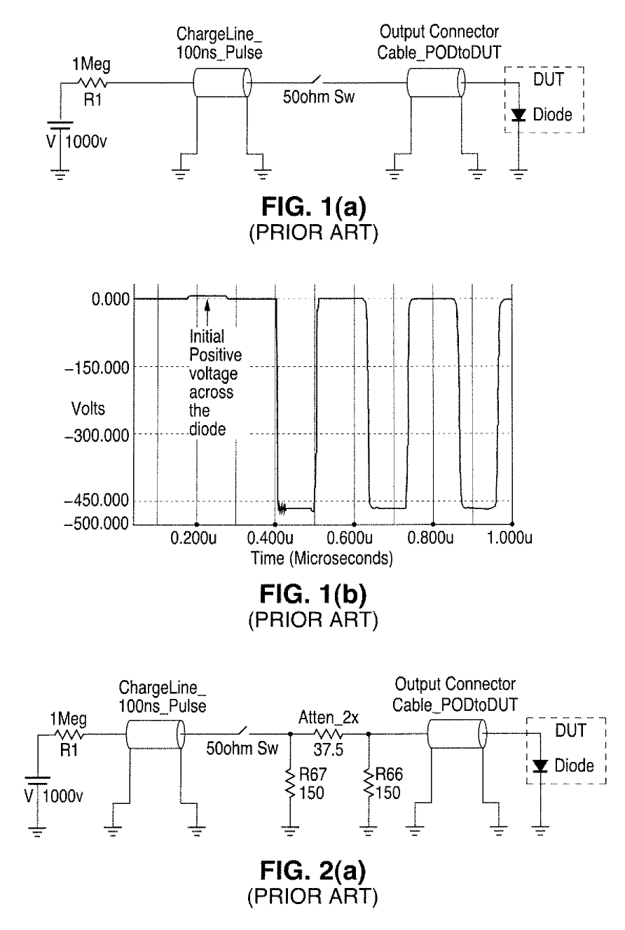

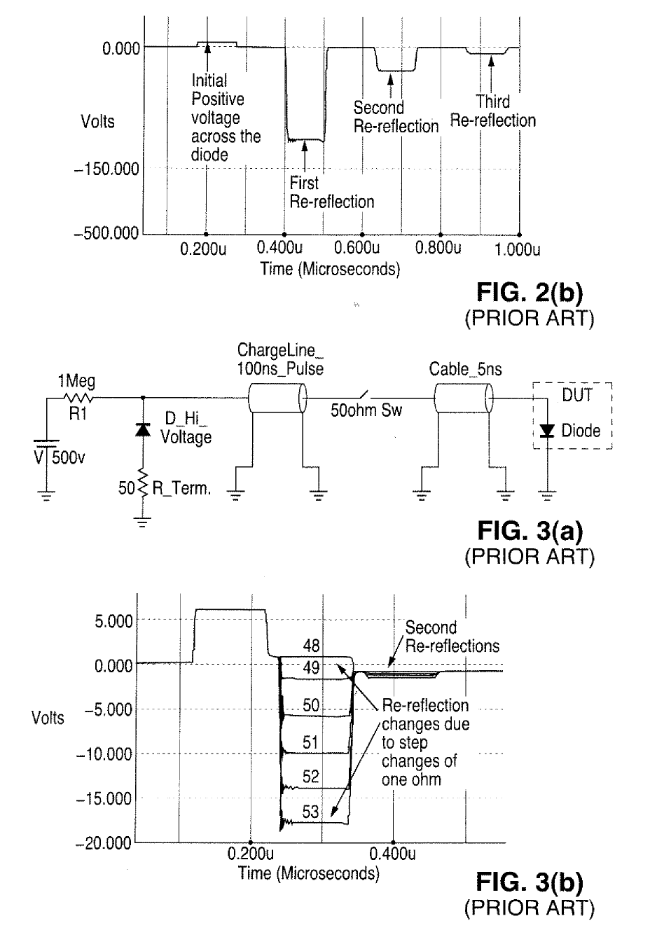

### DETAILED DESCRIPTION

In the following description, numerous specific details are provided, such as the identification of various system components, to provide a thorough understanding of embodiments of the invention. One skilled in the art will recognize, however, that the invention can be practiced without one or more of the specific details, or with other methods, components, materials, etc. In still other instances, well-known techniques, materials, or operations are not shown or described in detail to avoid obscuring aspects of various embodiments of the invention. Reference throughout this specification to “one embodiment” or “an embodiment” means that a particular feature, structure, or characteristic described in connection with the embodiment is included in at least one embodiment of the present invention. Thus, the appearance of the phrases “in one embodiment” or “in an embodiment” in various places throughout this specification are not necessarily all referring to the same embodiment. Furthermore, the particular features, techniques, structures, or characteristics may be combined in any suitable manner in one or more embodiments.

A TLP tester embodying the present invention may be viewed as a circuit with 4 major parts: a pulse generator, an electrical path delivering the pulses to the DUT, a pulse inverter inserted in the electrical path, and a DUT evaluation tester. A typical TLP evaluation tester will employ pulse current and/or voltage measuring probes in the electrical path to the DUT to sense the DUT's response to the TLP pulse, but these probes are not shown in the figures for clarity. While not required, a computer and interface circuitry is also typically used to coordinate TLP relay activation, set power supply levels, control the evaluation tester, and record test data. Determination of the stress level that induces DUT failure, a parameter usually determined during TLP testing, may also be done by a computer algorithm based on the collected data or by employing a Source-Meter Unit to measure DC characteristics of the DUT with high sensitivity. These common TLP extensions are not diagramed to avoid obscuring the invention.

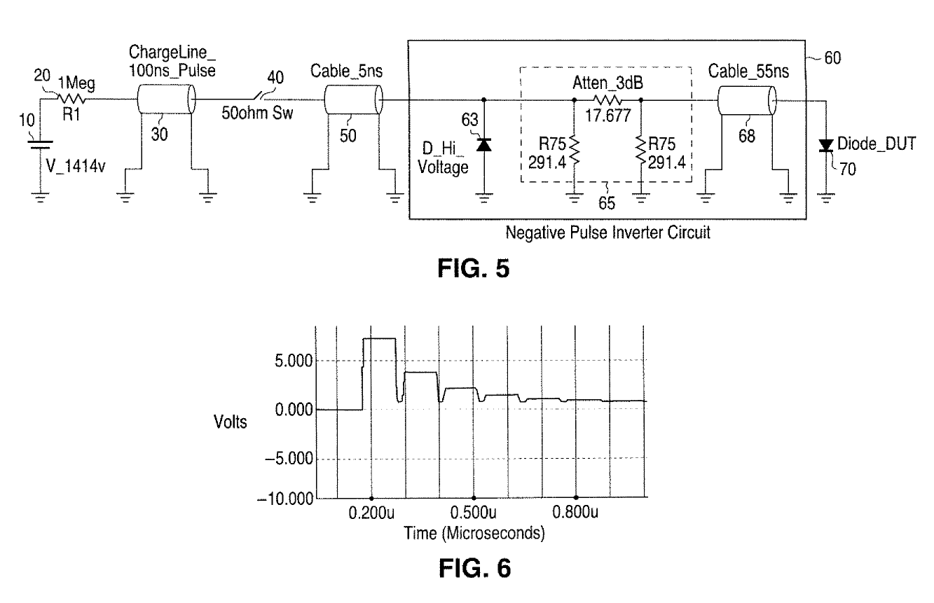

Referring to FIG. 5, a TLP tester according to the present invention is composed of a high voltage supply 10, a current limiting resistor 20 that isolates the charge-line cable 30, a 50-ohm switch 40 that closes to connect the charge-line cable 30 to the output cable 50 to thereby produce the test pulse, and a negative pulse inverter circuit 60 that conducts the test pulse to the DUT 70. Resistor 20 is large compared to the cable impedance, which allows slow charging of the charge-line cable 30 with current from the high voltage supply 10, but during the short TLP pulse, resistor 20 effectively blocks significant current, thereby isolating the charge-line, so that the connection between charge-line cable 30 and resistor 20 appears as an open circuit to pulses reflected back from the DUT. The negative pulse inverter circuit (NPI) 60 passes the initial positive pulse to the DUT with some attenuation. The NPI 60 is composed of a high voltage diode 63, a pulse attenuator 65 and a delay cable 68. The diode 63 has a reverse breakdown voltage that exceeds the maximum TLP pulse voltage that is incident at the cathode of the diode. Diode 63 must also be able to conduct the current of the maximum reflected pulse reduced by attenuator 65. The attenuator 65 is a symmetrical bidirectional resistive attenuator commonly used in RF and microwave systems. Attenuator 65 is shown in FIG. 5 as three resistors connected in a pi configuration. Other known types of attenuators can also be used. Cable 68 is of a length that it has a signal propagation delay equal to or greater than half of the TLP pulse width, thereby fully separating in time the incident and reflected pulses if these pulses are measured at the position of diode 63.

The operation of the NPI is to pass a positive incident pulse to the DUT, and if the DUT produces a negative polarity reflection (which will happen if the DUT in response to the incident pulse has an impedance of less than 50 ohms), that reflection will be re-inverted to a positive re-reflection that will travel back to the DUT. During the transmission of the reflections between diode 63 and the DUT 70, the pulse passes through attenuator 65 each time and is reduced in power. In the preferred embodiment of FIG. 5, the attenuator 65 is 3 dB, meaning that each time the pulses pass through it they are reduced by half in power. The value of attenuation is selected as a compromise between a desire for a maximum attenuation of re-reflections and a minimum attenuation of the incident pulse. The re-reflections pass through the attenuator 65 twice as the pulses travel between the DUT 70 to the diode 63 and back to the DUT, thereby reducing the power in the re-reflection to one-fourth. Subsequent re-reflections will be again reduced by a power factor of 4 from the previous re-reflection. The reflections will continue until the power of the reflections is mostly dissipated in attenuator 65.

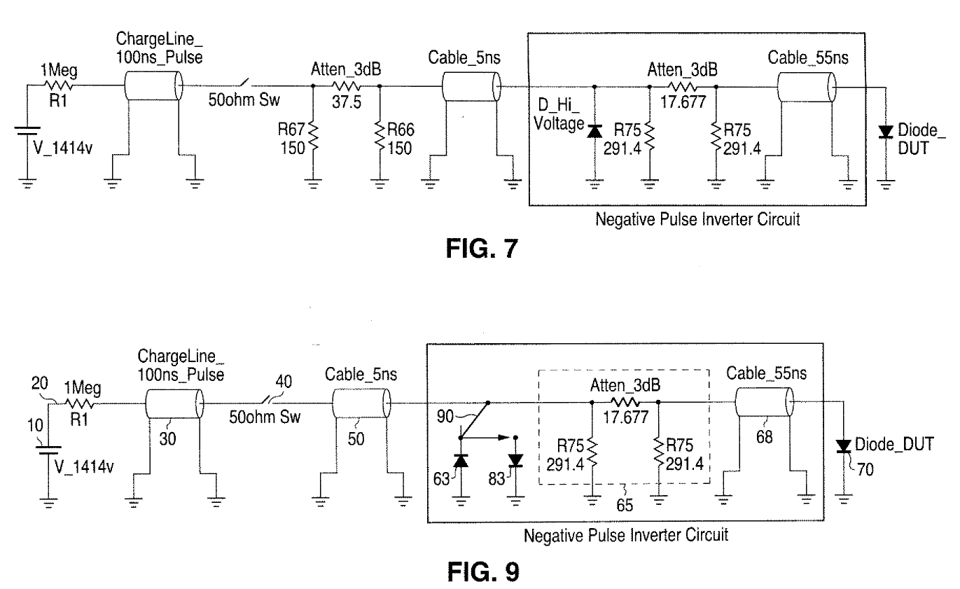

In another embodiment of the present invention, the NPI is combined with another attenuator such as typically used in TLP testers, as diagrammed in FIG. 7. This is convenient as this allows the NPI to be added to existing testers. This also has the benefit that non-negative reflections from positive incident pulses, which will not be re-inverted, will travel back to the charge-line and be re-reflected. The additional attenuator will reduce this polarity reflection.

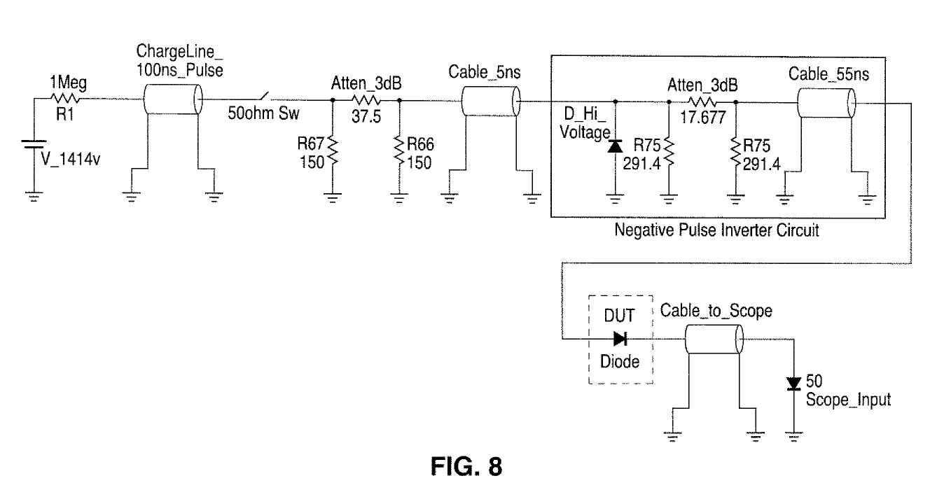

In another embodiment of the present invention, the ground return path of the DUT is replaced by a 50-ohm cable connected to a 50-ohm input of an oscilloscope, to thereby change to a TDRT configuration, as shown in FIG. 8. This reduces the current level that must be handled by the inverting diode 63, and is best when used with a second attenuator as in the previous embodiment. It is a common practice when using this configuration to protect the input to the oscilloscope with one or more additional attenuators due to the high power nature of a typical TLP pulse.

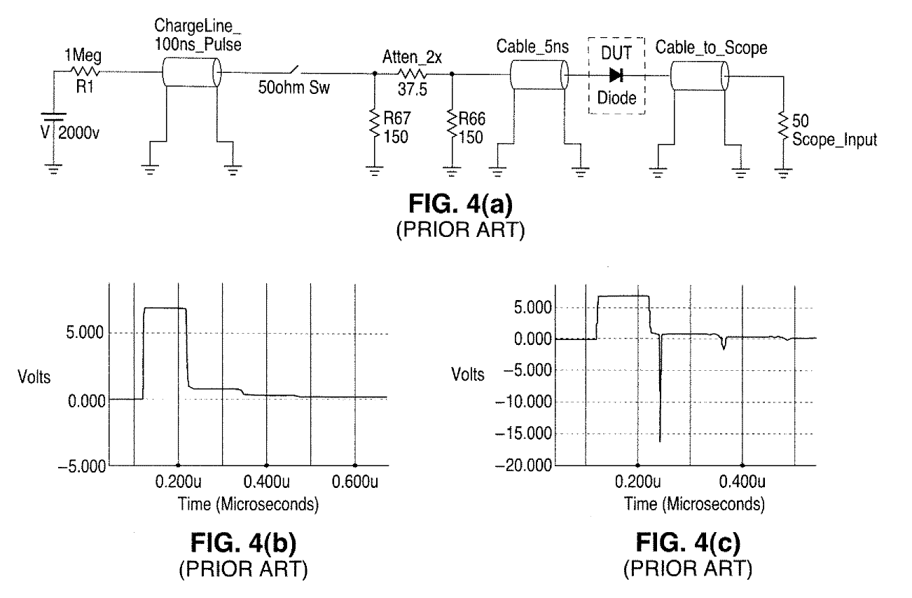

When the invention is used with devices under test that produce negative spike re-reflections, such as seen in prior art FIG. 4c, a further embodiment includes the addition of a conventional low pass filter circuit in the transmission path to reduce such high frequency spikes.

Some TLP testers will generate both positive and negative pulses during the testing. When using negative incident pulses, the connections of the diode 63 should be reversed to re-invert positive reflections. This reversal may be accomplished by using two diodes that are alternately connected to the transmission path by a relay switch. FIG. 9 is a simplified schematic electrical diagram of a fourth embodiment of a TLP system according to the present invention including two diodes, 63 and 93, that are alternately connected to the transmission path by a relay switch 90.

TABLE 1
Comparison of Components and Parameters for Prior Art and Invention

| Type of | | | Terminated | | TDRT | Pulse | Pulse |
|---|---|---|---|---|---|---|---|
| solution to | | Terminated | charge line | TDRT | 100 ohms | Inverter with | Inverter with |
| negative | 20 dB | charge | and 6 dB | 100 | and 6 dB | single 3 dB | 6 dB and 3 dB |
| reflections | attenuator | line | attenuator | ohms | attenuator | attenuator | attenuators |
| Prior art/ | Prior Art | Prior | Prior Art | Prior | Prior Art | Invention | Invention |
| invention | | Art | | Art | | | |
| Charge line | 5000 V | 500 V | 1000 V | 1000 V | 2000 V | 707 V | 1414 V |
| Voltage for | | | | | | | |
| 10 A DUT | | | | | | | |
| Attenuator(s)/ | 500 KW | 5 KW | 18.75 KW | 5 KW | 15 to 20 | 2.5 KW | 7.5 to 9.4 |
| Terminator | attenuator | resistor | attenuator/ | scope | KW and | attenuator | KW, and 1.9 |
| dissipation for | | | 1.25 KW | attn. | 5 KW | | to 2.5 KW |
| 10 A DUT | | | resistor | | scope | | |
| current | | | | | | | |
| Needed Diode | N/A | 500 V | 1 KV | N/A | N/A | 354 V | 354 V |
| Breakdown | | | | | | | |
| for 10 A DUT | | | | | | | |
| Attenuator/ | 2 MW | 20 KW | 75 KW/ | 20 KW | 60 to 80 | 10 KW | 30 to 37.5 |
| Terminator | attenuator | resistor | 5 KW | scope | KW and | attenuator | KW, and 7.5 |
| dissipation for | | | | atten. | 20 KW | | to 10 KW |
| 20 A DUT | | | | | scope | | attenuator |
| current | | | | | | | |
| Needed Diode | N/A | 1 KV | 2 KV | N/A | N/A | N/A | 707 V |
| Breakdown | | | | | | | |
| for 20 A DUT | | | | | | | |

Table 1 shows the relative power that must be dissipated, and voltage levels that must be withstood, by key components in the prior art and the invention. Improvement is demonstrated by the invention when either the voltage or the power levels are lower.

Although the present invention has been described in terms of the presently preferred embodiment, it is to be understood that such disclosure is not to be interpreted as limiting. Various alternations and modifications will no doubt become apparent to those skilled in the art after reading the above disclosure.

What is claimed is:

1. A Transmission Line Pulse (TLP) testing system for preventing negative pulse re-reflections from being coupled to a device under test (DUT) when the DUT is a low impedance, comprising:
a pulse generator for generating a voltage pulse;
a first cable having an input terminal coupled to said pulse generator, an output terminal, and at least one ground return terminal, for coupling said voltage pulse to the DUT when it is coupled to said output terminal; and
a negative pulse inverter circuit coupled between the first cable and the DUT for coupling the voltage pulse to the DUT so as to reduce said negative pulse re-reflections.

2. The TLP testing system of claim 1, wherein the negative pulse inverter circuit comprises:
a high voltage diode;
a pulse attenuator for reducing the magnitude of re-reflected pulses; and
a second cable coupled between the pulse attenuator and the DUT, wherein the high voltage diode has one end coupled to a junction of the first cable and the pulse attenuator and another end coupled to ground.

3. The TLP testing system of claim 2, wherein the second cable is configured as a delay cable of a predetermined length for causing the voltage pulse and the negative pulse reflection from the DUT to be separated a sufficient amount to enable isolation of the negative pulse reflection from the voltage pulse.

4. The TLP testing system of claim 2, wherein the pulse attenuator provides a 3 dB attenuation.

5. The TLP testing system of claim 2, wherein the pulse attenuator comprises:
a first resistor connected between the junction of the first cable and the high voltage diode, a second resistor connected in parallel with a third resistor through the first resistor; the junction of the first and third resistors connected to the second cable.

6. The TLP testing system of claim 2, wherein the high voltage diode has an anode coupled to ground and a cathode coupled to the junction of the pulse attenuator and the first cable.

7. The TLP testing system of claim 2, further comprising another attenuator coupled between the pulse generator and the first cable.

8. The TLP testing system of claim 7, further comprising a third cable connected to a 50-ohm input of an oscilloscope, wherein the DUT is connected between the third cable and the negative pulse inverter circuit.

9. The TLP testing system of claim 1, further comprising a low pass filter circuit coupled between the pulse generator and DUT to reduce high frequency spikes.

10. The TLP testing system of claim 2, further comprising a second high voltage diode connected to the first cable with the opposite polarity of the connection of the high voltage diode to the first cable; and further comprising a relay switch to alternately connect each high voltage diode to the first cable.

11. In a Transmission Line Pulse (TLP) testing system having a pulse generator for generating a voltage pulse and a first cable having an input terminal coupled to said pulse generator, an output terminal, and at least one ground return terminal, for coupling said voltage pulse to a device under test (DUT) when it is coupled to said output terminal, a negative pulse inverter circuit coupled between the first cable and the DUT to prevent negative pulse re-reflections from being coupled to the DUT when the DUT is a low impedance, the negative pulse inverter circuit comprising:
a high voltage diode;
a pulse attenuator for reducing the magnitude of re-reflected pulses;
a second cable coupled between the pulse attenuator and the DUT, wherein the high voltage diode has one end coupled to a junction of the first cable and the pulse attenuator and another end coupled to ground.

12. The negative pulse inverter circuit of claim 11, wherein the second cable has a predetermined length for causing the second cable to provide a signal propagation delay equal to or greater than half of the width of the voltage pulse.

13. The negative pulse inverter circuit of claim 11, wherein the TLP testing system has another attenuator coupled between the pulse generator and the first cable.

14. The negative pulse inverter circuit of claim 13, further comprising a third cable connected to a 50-ohm input of an oscilloscope, wherein the DUT is connected between the third cable and the pulse inverter circuit.

15. The negative pulse inverter circuit of claim 11, further comprising another high voltage diode connected to the first cable with the opposite polarity of the connection of the other high voltage diode to the first cable; and further comprising a relay switch to alternately connect each high voltage diode to the first cable.

16. The negative pulse inverter circuit of claim 11, wherein the high voltage diode has an anode coupled to ground and a cathode coupled to the junction of the pulse attenuator and the first cable.

17. The negative pulse inverter circuit of claim 11, wherein the pulse attenuator comprises:
a first resistor connected between the junction of the first cable and the high voltage diode, a second resistor connected in parallel with a third resistor through the first resistor; the junction of the first and third resistors connected to the second cable.

18. The negative pulse inverter circuit of claim 11, wherein the second cable has a predetermined length for causing the voltage pulse and the negative pulse reflection from the DUT to be separated a sufficient amount to enable isolation of the negative pulse reflection from the voltage pulse.

19. A method of preventing negative pulse re-reflections for a Transmission Line Pulse (TLP) testing system when a device under test (DUT) is a low impedance, the method comprising:
coupling a positive voltage pulse from a pulse generator to the DUT; and
if the DUT produces a negative polarity reflection, performing the following steps:
attenuating the negative polarity reflection;
inverting the attenuated negative polarity reflection to a positive re-reflection;
attenuating the positive re-reflection; and
coupling the attenuated positive re-reflection back to the DUT.

20. The method of claim 19, wherein each attenuating is a 3 dB attenuation, such that the attenuated positive re-reflection has about one fourth the power of the negative polarity reflection.
